(19) United States
(12) Patent Application Publication
(10) Pub. No.: US 2025/0385211 A1
(43) Pub. Date: Dec. 18, 2025

(54) PACKAGE STRUCTURE AND PACKAGING METHOD

(71) Applicant: SUREWAY TECHNOLOGY CO.,LTD., Taichung City (TW)

(72) Inventors: Hsing-Hua TSAI, Taichung City (TW); Song-Huan SUN, Taichung City (TW); Ming-Chih HSU, Taichung City (TW); Tung-Han CHUANG, Taichung City (TW); Chih-Hsin TSAI, Taichung City (TW)

(73) Assignee: SUREWAY TECHNOLOGY CO.,LTD., Taichung City (TW)

(21) Appl. No.: 18/945,688

(22) Filed: Nov. 13, 2024

(30) Foreign Application Priority Data
Jun. 13, 2024 (TW) 113121773

(51) Int. Cl. H01L 23/00; H01L 23/367; H01L 23/373; H01L 25/065

(52) U.S. Cl. CPC H01L 24/29; H01L 23/3675; H01L 23/3735; H01L 23/3738; H01L 24/32; H01L 24/83; H01L 25/0655; H01L 2224/29109; H01L 2224/29113; H01L 2224/29582; H01L 2224/29624; H01L 2224/29639; H01L 2224/29644; H01L 2224/29647; H01L 2224/29655; H01L 2224/29664; H01L 2224/29666; H01L 2224/29669; H01L 2224/29671; H01L 2224/29672; H01L 2224/29673; H01L 2224/29678; H01L 2224/29684; H01L 2224/32225; H01L 2224/32245; H01L 2224/83009; H01L 2224/8302; H01L 2224/83203; H01L 2924/01047; H01L 2924/0105; H01L 2924/01083; H01L 2924/16235

(57) ABSTRACT

A package structure includes a substrate, a chip disposed on the substrate and having a backside surface away from the substrate, a heat sink disposed above the substrate and having a surface facing the back side surface, and a thermal interface material disposed between the chip and the heat sink. There is no organic adhesive between the chip and the heat sink. A method for forming the package structure is also provided.

### CROSS-REFERENCE TO RELATED APPLICATIONS

This application claims priority of Taiwan Patent Application No. 113121773, filed on Jun. 13, 2024, the entirety of which is incorporated by reference herein.

### BACKGROUND OF THE INVENTION

### Technical Field

The present disclosure relates to a package technology, and, in particular, to a package structure and a packaging method.

### Description of the Related Art

Electronic components are developing in the direction of being light, thin, short, and small, and having high performance, high transmission, and high efficiency, and the heat output generated per unit area is also getting higher and higher. For example, in the past, a central processing unit (CPU) element using a Pentium processor had a heating value of only 20 W, but a Pentium 4 exceeded 80 W, and the temperature of the CPU during operation might reach over 150° C. According to predictions about the future trends in the development of the semiconductor industry, made by the U.S. International Technology Roadmap for Semiconductors (ITRS), the heat output of low-level computers will increase in the next few years from the current level of approximately 100 W to nearly 120 W, and the heat output of high-level computers will increase significantly from the original 150 W to more than 180 W. Their working frequency will also increase from 2 GHz to 4 GHz or more. When the functionality and heat power density of an electronic component both increase significantly, the requirements on heat management must become increasingly stringent.

Thermal interface materials (TIM) are a type of material commonly used in integrated circuit (IC) packaging and electronic component heat dissipation. The main function of thermal interface material is to fill the contact gaps between two materials, to increase the heat dissipation performance of the system, and to effectively reduce the thermal impedance. A good thermal interface material should possess the following characteristics: (1) good heat dissipation properties, that is, high heat conductivity and low thermal impedance value; (2) ease of assembly and reworkability; (3) higher compressibility to withstand external compressive stress when being affixed to a bonding surface, and to properly fill the gaps between interfaces to facilitate heat flow propagation; (4) good wettability with electronic components and heat sinks; and (5) high reliability and long service life. Current thermal interface material mainly includes thermal grease, elastomeric thermal pad, phase change material, and low melting alloy, and so on.

While existing package technologies that use thermal interface materials have generally been adequate for their intended purposes, they have not been entirely satisfactory in all respects, and there is still room for improvement in terms of process simplification and manufacturing cost.

### BRIEF SUMMARY OF THE INVENTION

An embodiment of the present disclosure provides a package structure. The package structure includes a substrate, a chip disposed on the substrate and having a backside surface away from the substrate, a heat sink disposed above the substrate and having a surface facing the back side surface, and a thermal interface material disposed between the chip and the heat sink, and there is no organic adhesive between the chip and the heat sink.

An embodiment of the present disclosure provides a packaging method. The package method includes disposing a chip on a substrate, in which the chip has a backside surface away from the substrate. The packaging method includes providing a heat sink, in which the heat sink has a surface facing the backside surface of the chip. The packaging method includes disposing a thermal interface material onto the chip or the heat sink via indentation bonding. The packaging method includes bonding the heat sink to the chip so that the thermal interface material is disposed between the chip and the heat sink.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIGS. 1-4 are cross-sectional views of various stages of manufacturing a package structure, in accordance with some embodiments.

FIG. 5 is a cross-sectional view of a package structure, in accordance with some embodiments.

FIGS. 6-8 are cross-sectional views of various stages of manufacturing a package structure, in accordance with other embodiments.

FIGS. 9-13 are cross-sectional views of various forms of a package structure, in accordance with further embodiments.

### DETAILED DESCRIPTION OF THE INVENTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

In the existing technology, in order to prevent a thermal interface material from slipping out of place being pressed between the heat sink and the chip (thereby failing to fill the contact gaps between them), an organic adhesive must first be used to attach the thermal interface material to the heat sink or the chip. Therefore, in the package structure obtained by pressing the chip and the heat sink, there will be an organic adhesive (such as fixing adhesive, flux, and so on) between the heat sink and the chip, and the heat dissipation performance can be affected by the property of the organic adhesive itself. In addition, the cost of acquiring and disposing the organic adhesive will lead to an increase in the overall production cost. Moreover, solid residues from the organic adhesive may remain at the bonding interface, creating voids that reduce the reliability of the package structure. This can also prevent the thermal interface material from fully adhering to the chip and heat sink, leading to diminished thermal dissipation performance

To solve the above problems, the present disclosure uses an indentation bonding technique which eliminates the need for additional organic adhesives and allows for the fixation of the thermal interface material at room temperature (above 0° C.). By applying pressure to the thermal interface material before pressing the chip and heat sink together, the thermal interface material is directly contacted and fixed onto the chip or heat sink, achieving temporary positioning. This prevents the thermal interface material from slipping out of place before the chip and heat sink are pressed together, thereby eliminating the need for the organic adhesive used in the existing techniques. Therefore, the package structure and the packaging method provided by the present disclosure may save the cost of acquiring and disposing the organic adhesive, and since the thermal interface material is in direct contact with the chip and the heat sink, rather being separated the organic adhesive, the heat generated during the operation of the chip can be directly transferred to the heat sink through the thermal interface material to achieve a better heat dissipation performance.

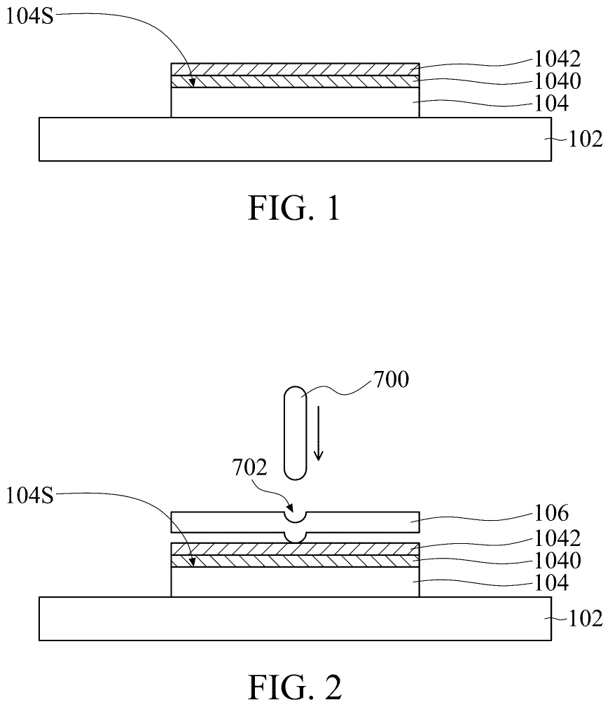

FIGS. 1-4 are cross-sectional views of various stages of manufacturing a package structure 100, in accordance with some embodiments.

Referring to FIG. 1, in an embodiment, a chip 104 is disposed on a substrate 102. In some embodiments, the substrate 102 may include a printed circuit board (PCB), a wafer substrate, an integrated circuit (IC), an interposer, a chip carrier, a circuit carrier, and display device. In some embodiments, the chip 104 may include a semiconductor chip. The semiconductor chip may be, for example, a small piece of the semiconductor wafer formed by separating the semiconductor wafer into individual dies after performing semiconductor processes on the semiconductor wafer. The chip 104 may include an integrated circuit for processing and/or storing data, such as field programmable gate array (FPGA), processing unit (such as graphics processing unit (GPU)), central processing unit (CPU), application specific integrated circuit (ASIC), memory device (such as memory controller or memory), and so on. In some embodiments, the chip 104 may include a single crystal of a material of Si, Ge, SiC, sapphire, GaAs, and GaN. In some embodiments, the chip 104 may be attached to the substrate 102 using a polymer adhesive, a solder, or a combination thereof.

In an embodiment, the chip 104 has a backside surface 104S away from the substrate 102 (the surface of the chip 104 facing upward in FIG. 1). In an embodiment, the chip 104 optionally includes a metal layer 1040 on the backside surface 104S and an outermost metal layer 1042 on the metal layer 1040. Specifically, the outermost metal layer 1042 is on a side of the metal layer 1040 away from the substrate 102. Specifically, the outermost metal layer 1042 is on a side of the metal layer 1040 away from the substrate 102. In some embodiments, the metal layer 1040 and the outermost metal layer 1042 are configured to enhance the heat dissipation performance of the package structure 100 and reduce the thermal impedance of the package structure 100, but the present disclosure is not limited thereto.

In some embodiments, the metal layer 1040 may include at least one of Al/Ti/NiV, Al/Cr/NiV, Al/NiV, Al/W, Ti/NiV, TiW, WTi, WTi/Ti, Cr/NiV, Cr, W, Ti/Ni, Al/Ti/Ni, and Ti. In some embodiments, the thickness of the metal layer 1040 may be 0.001 to 10 μm (such as 0.5 to 1.6 μm). The outermost metal layer 1042 may include at least one of Au, Ag, Cu, Rh, Ir, Pd, Pt, and any suitable metal material, and has a thickness of 0.001 to 10 μm (such as 0.1 to 2 μm). In some embodiments, the method for forming the metal layer 1040 and the outermost metal layer 1042 may include sputtering, evaporation, electroplating, and any suitable deposition process.

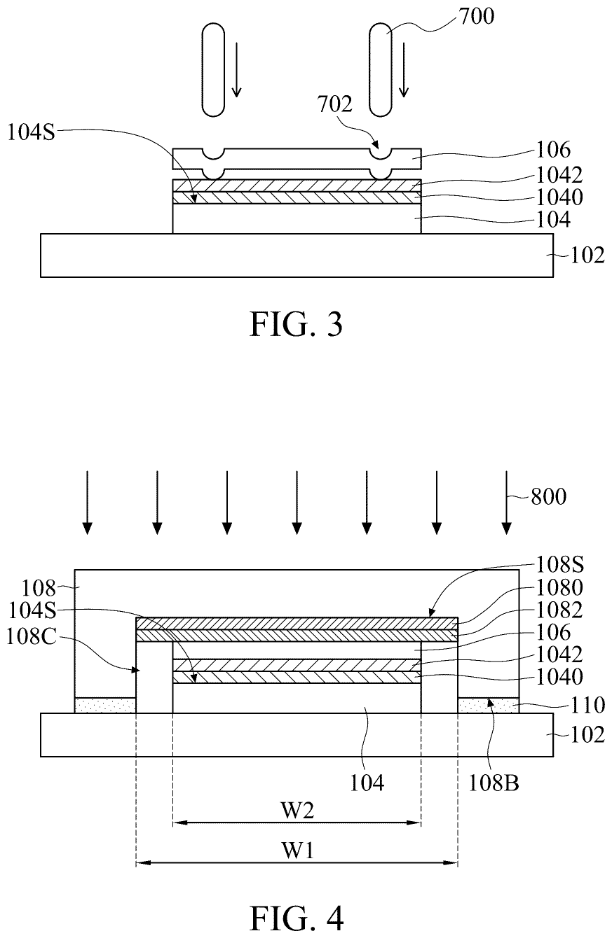

Referring to FIGS. 2-3, in an embodiment, a thermal interface material 106 is disposed onto the chip 104 through indentation bonding. In some embodiments, the thermal interface material 106 is configured to fill the contact gap between the chip 104 and a heat sink 108 (as illustrated in FIG. 4), enhance the overall heat dissipation performance of the package structure 100, and effectively reduce the thermal impedance of the package structure 100.

In some embodiments, the thermal interface material 106 is disposed on the chip 104 through indentation bonding. Specifically, referring to FIGS. 2-3, downward arrows represent the direction of applied pressure. By applying pressure to the thermal interface material 106 (e.g., using a press head 700), an indentation 702 is formed where the pressure is applied on the thermal interface material 106. Due to the applied pressure, a diffusion bond forms between the thermal interface material 106 and the chip 104, securing the thermal interface material 106 onto the chip 104 and achieving temporary positioning. This prevents the thermal interface material 106 from slipping out of place before the heat sink 108 (as shown in FIG. 4) and the chip 104 are pressed together, thereby eliminating the need for the step of applying an organic adhesive. In FIG. 2, a press head 700 is used to apply pressure at a single point to the thermal interface material 106 to form an indentation 702. In FIG. 3, two press heads 700 are used to apply pressure at multiple points to the thermal interface material 106. It should be noted that although only a single-point indentation and two-point indentation are illustrated in FIGS. 2-3, the present disclosure is not limited thereto. In other embodiments, pressure at a single point or multiple points may be applied at any position on a surface of the thermal interface material 106 to form an indentation at a single point, two or more points on the thermal interface material 106 according to practical requirements. For example, in FIGS. 2-3, a single-point or multi-point pressure is applied to the thermal interface material 106 in a direction toward a surface of the outermost metal layer 1042 of the chip 104 (such as using the press head 700). In addition, although the press head 700 and the indentation 702 as illustrated in FIGS. 2-3 have a circular profile, the present disclosure is not limited thereto. In other embodiments, the press head 700 may have a profile of any shape, and the indentation 702 has a profile corresponding to that of the press head 700. Moreover, although the side of the press head 700 for applying pressure at a single point or multiple points is shown as a hemisphere as illustrated in the drawings, the present disclosure is not limited thereto. In other embodiments, it may also have a different shape such as a strip, a box, a matrix, a polygon, an irregular shape, and so on.

In some embodiments, the indentation bonding may be performed by applying pressure to the surface of the thermal interface material 106 at a temperature above 0° C. (such as 5° C., 10° C., 15° C., 20° C., 25° C., 30° C., 35° C., 40° C., or greater than 40° C.), and the applied force may be greater than 0.1 gram-force/square millimeter (gf/mm²) and maintained for greater than 0.1 seconds (such as 0.5 seconds, 1 second, 5 seconds, 10 seconds, 15 seconds, 20 seconds, 25 seconds, 30 seconds, 45 seconds, 1 minute, or more than 1 minute) to affix the thermal interface material 106 onto the outermost metal layer 1042. In some embodiments, multi-point pressure is applied to the thermal interface material 106 during the indentation bonding, in which the force applied at each point is greater than 0.1 gram-force/square millimeter (gf/mm²) (such as 0.5 gram-force/square millimeter (gf/mm²), 1 gram-force/square millimeter (gf/mm²), 5 gram-force/square millimeter (gf/mm²), and so on).

In some embodiments, the thermal interface material 106 may include at least one of phase change material, metal alloy, and any other suitable thermal interface material. In some embodiments, the thermal interface material may include indium-based alloy. In the present disclosure, the term “indium-based alloy” used herein includes an alloy containing at least indium. The alloy containing indium may be formed of (1) indium and (2) at least one of Bi, Sn, and Ag such as indium-bismuth alloy, indium-bismuth-tin alloy, indium-tin alloy, or indium-silver alloy. In some embodiments, the indium-based alloy includes at least one of 30 to 35 wt % of Bi, 15 to 18 wt % of Sn and a balance of In, with a melting point of 55 to 65° C.; 30 to 35 wt % of Bi and a balance of In, with a melting point of 70 to 75° C.; 52 to 60 wt % of Bi, 15 to 18 wt % of Sn and a balance of In, with a melting point of 80 to 85° C.; 48 to 50 wt % of Sn and a balance of In, with a melting point of 110 to 120° C.; and 0.1 to 15 wt % of Ag and a balance of In, with a melting point of 140 to 280° C. In some embodiments, the thermal interface material may be pure indium and has a melting point of 150 to 160° C.

Referring to FIG. 4, in an embodiment, the heat sink 108 is provided. In some embodiments, the heat sink 108 may be a heat-dissipating metal lid and/or a cooling fin, but the present disclosure is not limited thereto. Any type and shape of heat dissipating device (such as heat pipe, cooling fan, water-cooling circulation thermal element, and other suitable heat dissipating element) can be selected according to practical requirements. As shown in drawings, in an embodiment, the heat sink 108 is a heat-dissipating metal lid with a recess 108C for accommodating the chip 104.

In some embodiments, the recess 108C is on the side of the heat sink 108 adjacent to the chip 104 (the surface of the heat sink 108 facing downward in FIG. 4), and a lateral width W1 of the recess 108C is greater than a lateral width W2 of the chip 104 to ensure that the chip 104 can be accommodated within the recess 108C when the heat sink 108 and the chip 104 are pressed together (FIG. 4). In some embodiments, the material of the heat sink 108 may include metal and/or metal alloy such as Cu, Al, Co, Ni, nickel-plated copper, a combination thereof, or any suitable metal material. In other embodiments, the heat sink 108 may also be made of composite material such as an alloy, silicon carbide, aluminum nitride (AlN), graphite, the like, or a combination thereof.

In an embodiment, the heat sink 108 has a surface 108S facing the backside surface 104S of the chip 104. In an embodiment, the surface 108S of the heat sink 108 (the surface of the heat sink 108 facing downward in FIG. 4) is on the recess 108C of the heat sink 108. In an embodiment, the heat sink 108 optionally includes a metal layer 1080 on the surface 108S and an outermost metal layer 1082 on the metal layer 1080. Specifically, the outermost metal layer 1082 is on a side of the metal layer 1080 away from the heat sink 108. In some embodiments, the metal layer 1080 and the outermost metal layer 1082 are configured to enhance the heat dissipation performance of the package structure 100 and reduce the thermal impedance of the package structure 100, but the present disclosure is not limited thereto.

In some embodiments, the metal layer 1080 may include at least one of Au, Ag, Cu, Ti, Ti/Ni, Ni, and W. In some embodiments, a thickness of the metal layer 1080 may be 0.001 μm to 10 μm (such as 0.5 μm to 1.6 μm). In some embodiments, the outermost metal layer 1082 may include at least one of Au, Ag, Cu, Rh, Ir, Pd, Pt, and any suitable metal material, and has a thickness of 0.001 μm to 10 μm (such as 0.1 μm to 2 μm). In some embodiments, the method for forming the metal layer 1080 and the outermost metal layer 1082 may include sputtering, evaporation, electroplating, or any suitable deposition process.

Still referring to FIG. 4, in an embodiment, the heat sink 108 is bonded to the chip 104 in such a way that the thermal interface material 106 is disposed between the chip 104 and the heat sink 108. In an embodiment, an adhesive 110 is applied on the substrate 102, and then a bottom surface 108B of the heat sink 108 is bonded to the substrate 102 through the adhesive 110, and the heat sink 108 is in direct contact with the thermal interface material 106 so that the thermal interface material 106 is in direct contact with both chip 104 and the heat sink 108 at the same time. Then, the thermal interface material 106 is melted through a hot press process 800, which simultaneously soft-bakes the adhesive 110 (that is, turning the adhesive 110 into a partially-cured adhesive 110C). In this way, the process may be simplified, and the production cost and the production time may be reduced.

In an embodiment, the hot press process 800 may include: applying a force greater than 1 gram-force/square centimeter (gf/cm²) (such as 55 gram-force/square centimeter, 900 gram-force/square centimeter, 3700 gram-force/square centimeter, and so on) on the heat sink 108 in a process chamber at a temperature above 50° C. (such as 135° C., 145° C., 155° C., 165° C., and so on) for a period of 2 seconds to 10 minutes (such as 5 seconds, 10 seconds, 20 seconds, 30 seconds, 45 seconds, 1 minute, 3 minutes, 5 minutes, and so on). In addition, the process chamber for performing the hot press process 800 may be a process chamber under pressure or vacuum. The process chamber under pressure refers to a process chamber with a chamber pressure greater than 1 atmosphere. The process chamber under vacuum refers to a process chamber with a chamber pressure lower than 1 atmosphere. By performing the hot press process 800 in a process chamber under pressure or vacuum, the residual gas in the thermal interface material 106 may be effectively expelled, and thus reduce the likelihood of voids forming between the thermal interface material 106 and the chip 104 and between the thermal interface material 106 and the heat sink 106, and increase the coverage of the thermal interface material 106 on the chip 104 (such as greater than 90%, greater than 95%, or greater than 99%). This approach helps to improve the reliability and heat dissipation performance of the package structure 100. The term “coverage” used herein refers to the ratio of the projected area of the thermal interface material 106 on the chip 104 projected onto the surface 108S of the heat sink 108 by an ultrasonic wave or X-ray to the projected area of the chip 104 projected onto the surface 108S of the heat sink 108 after the packaging process is completed. Generally, a higher coverage indicates fewer voids generated in the thermal interface material 106.

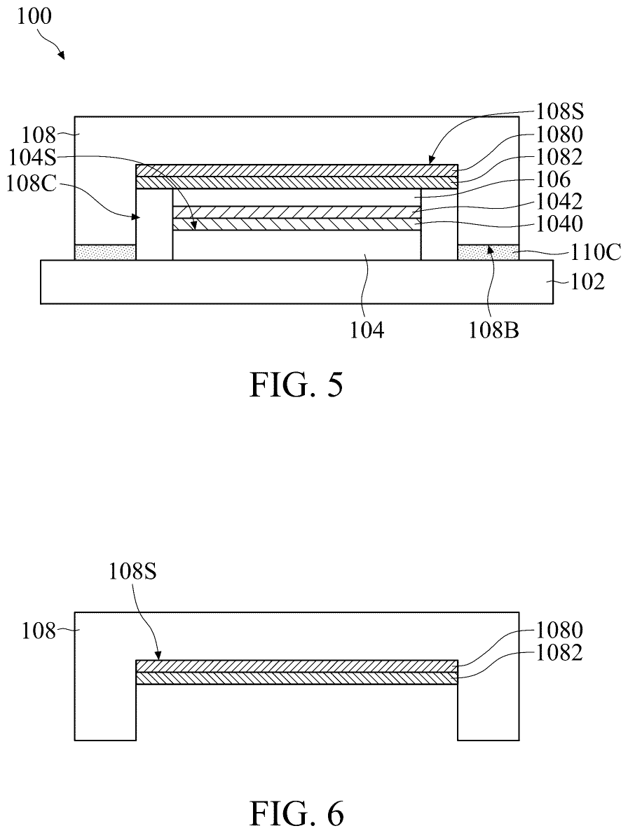

FIG. 5 is a cross-sectional view of a package structure, in accordance with some embodiments. The package structure 100 includes the substrate 102, the chip 104 disposed on the substrate 102, the heat sink 108 disposed above the substrate 102, and the thermal interface material 106 disposed between the chip 104 and the heat sink 108. The chip 104 has the backside surface 104S away from the substrate 102. The heat sink 108 has the surface 108S facing the backside surface 104S of the chip 104. There is no organic adhesive between the chip 104 and the heat sink 108. In an embodiment, the thermal interface material 106 is in direct contact with the outermost metal layer 1042 of the chip 104 and the outermost metal layer 1082 of the heat sink 108.

Still referring to FIG. 5, since there is no organic adhesive between the chip 104 and the heat sink 108, the risk of solid residue from the organic adhesive causing voids at the bonding interface may be avoided, and the reliability and heat dissipation performance of the package structure 100 are further enhanced. Therefore, in the present embodiment, the heat generated during the operation of the chip 104 may be directly transferred to the heat sink 108 through the thermal interface material 106. By comparison, in the existing art, the organic adhesive (such as fixing adhesive, flux, and so on) is present between the chip and the heat sink, so the heat dissipation performance can be affected by the property of the organic adhesive itself, and the solid residues from the organic adhesive may remain at the bonding interface, creating voids. This can also prevent the thermal interface material from fully adhering to the chip and the heat sink, leading to diminished thermal dissipation performance.

FIGS. 6-8 are cross-sectional views of various stages of manufacturing a package structure, in accordance with other embodiments. It should be noted that some processes or devices are the same as, or similar to, those described in the embodiments above, and therefore the reference numerals and/or letters may be repeated. Compared with the embodiments above in which the thermal interface material 106 is disposed on the chip 104, the thermal interface material 106 of this embodiment is first disposed on the heat sink 108 through indentation bonding.

Referring to FIG. 6, in some embodiments, the heat sink 108 is provided. In the present embodiment, the heat sink 108 is the heat-dissipating metal lid, and thus the heat sink 108 has the recess 108C for accommodating the chip 104, but the present disclosure is not limited thereto. Any type and shape of heat dissipating device (such as a heat pipe, a cooling fan, a water-cooling circulation thermal element, or other suitable heat dissipating element) can be selected according to practical requirements.

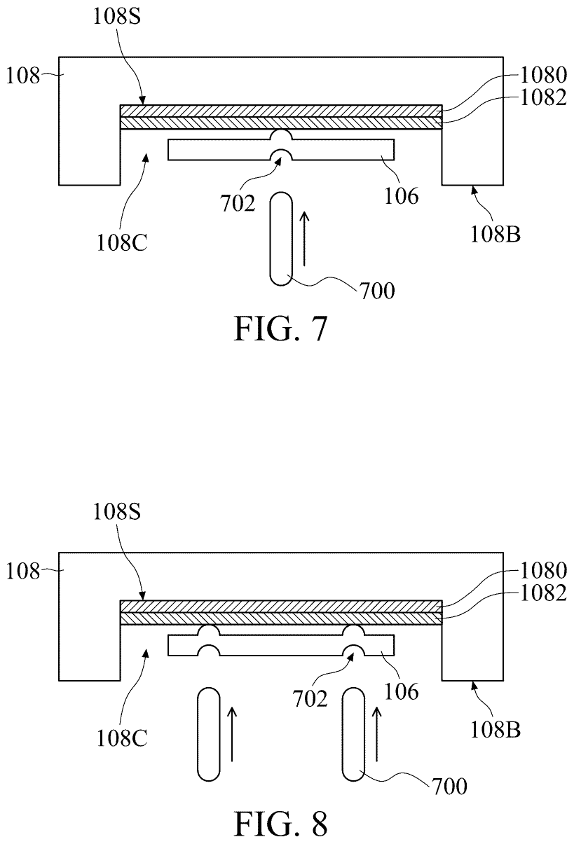

Referring to FIGS. 7-8, the thermal interface material 106 is disposed on the heat sink 108. The thermal interface material 106 is disposed on the heat sink 108 through indentation bonding. Specifically, downward arrows as shown in FIGS. 7-8 represent the direction of applied pressure. By applying pressure to the thermal interface material 106 (e.g. using a press head 700), an indentation 702 is formed where the pressure is applied on the thermal interface material 106. Due to the applied pressure, a diffusion bond forms between the thermal interface material 106 and the chip 104, securing the thermal interface material 106 onto the chip 104 and achieving temporary positioning. This prevents the thermal interface material 106 from slipping out of place before the heat sink 108 (as shown in FIG. 4) and the chip 104 are pressed together, thereby eliminating the need for the step of applying an organic adhesive. In FIG. 7, the press head 700 is used to apply pressure at a single point to the thermal interface material 106 to form the indentation 702. In FIG. 8, two press heads 700 are used to apply pressure at multiple points to the thermal interface material 106. It should be noted that although only a single-point indentation and two-point indentation are illustrated in the drawings, the present disclosure is not limited thereto. In other embodiments, a single-point pressure or multi-point pressure may be applied at any position on a surface of the thermal interface material 106 to form an indentation at a single point, two or more points on the thermal interface material 106 according to practical requirements. For example, in FIGS. 7-8, a single-point or multi-point pressure is applied to the thermal interface material 106 in a direction toward a surface of the outermost metal layer 1082 of the heat sink 108 (such as using the press head 700). In addition, although the press head 700 and the indentation 702 as illustrated in the drawings have a circular profile, the present disclosure is not limited thereto. In other embodiments, the press head 700 may have a profile of any shape, and the indentation 702 has a profile corresponding to that of the press head 700.

In some embodiments, the indentation bonding may be performed by applying pressure to the surface of the thermal interface material 106 at the temperature above 0° C., and the applied force may be greater than 0.1 gram-force/square millimeter (gf/mm²) and maintained for greater than 0.1 seconds to affix the thermal interface material 106 onto the outermost metal layer 1082. In some embodiments, multi-point pressure is applied to the thermal interface material 106 during the indentation bonding, in which the force applied at each point is greater than 0.1 gram-force/square millimeter (gf/mm²).

FIGS. 7-8 are followed by FIGS. 4-5, in an embodiment, the heat sink 108 is bonded to the chip 104 in such a way that the thermal interface material is disposed between the chip 104 and the heat sink 108. In an embodiment, the adhesive 110 is applied on the substrate 102, and then the bottom surface 108B of the heat sink 108 is attached to the substrate 102 through the adhesive 110, and the heat sink 108 is in direct contact with the thermal interface material 106 so that the thermal interface material 106 is in direct contact with both the chip 104 and the heat sink 108 at the same time. Then, the thermal interface material 106 is melted through the hot press process 800, which simultaneously soft-bakes the adhesive 110 (that is, turning the adhesive 110 into a partially-cured adhesive 110C). This simplifies the process and lowers both the production cost and the production time.

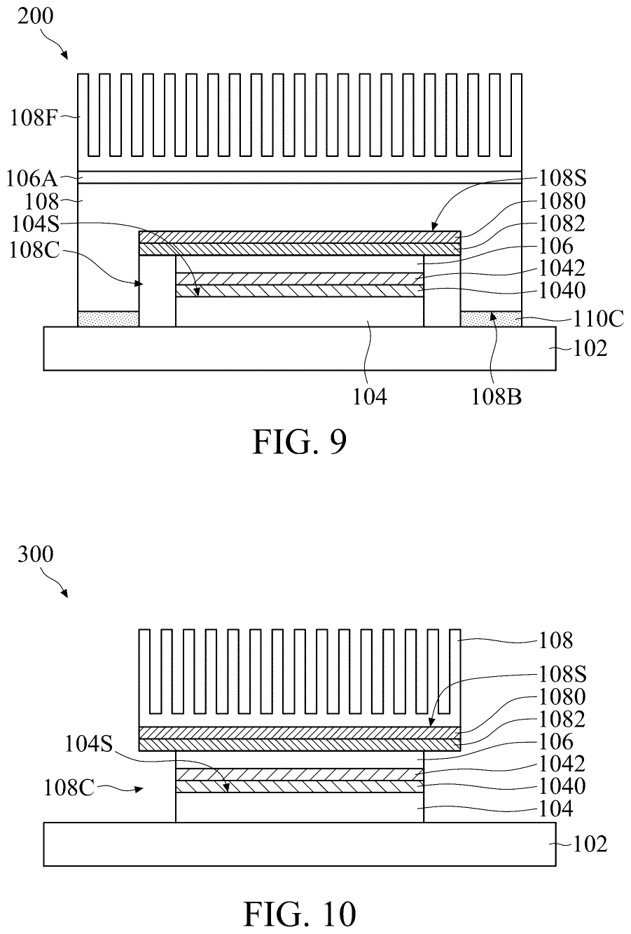

FIGS. 9-13 are cross-sectional views of various forms of a package structure 200, 300, 400, 500, 600, in accordance with other embodiments.

In some embodiments, the package structure 200 as shown in FIG. 9 is similar to the package structure 100 as shown in FIG. 5, except that the heat sink 108 bonded to the substrate is the heat-dissipating metal lid, and after the heat sink 108 is bonded to the chip 104, another heat sink 108F is disposed on the heat-dissipating metal lid, in which the heat sink 108F is the cooling fin. Therefore, a heat dissipation area is further increased by the cooling fin. Specifically, in an embodiment, after the heat sink 108 is bonded to the chip 104, a thermal interface material 106A is disposed on a surface of the heat sink 108 away from the chip 104, and then the heat sink 108F is disposed on the thermal interface material 106A. The thermal interface material 106A can be similarly positioned on the heat sink 108 using indentation bonding, allowing the thermal interface material 106A to form a diffusion bond on the surface of the heat sink 108 that is away from the chip 104. Subsequently, after placing the heat sink 108F on the thermal interface material 106A, the hot press process 800 (as illustrated in FIG. 4) can be used to melt the thermal interface material 106A, filling the contact gaps between the heat sinks 108 and 108F. In some embodiments, the package structure 300 as shown in FIG. 10 is similar to the package structure 100 as shown in FIG. 5, except that the heat sink 108 is the cooling fin. Since the cooling fin has a larger heat dissipation area compared with the heat-dissipating metal lid, and thus it may conduct the heat generated during the operation of the chip 104 more quickly to achieve better heat dissipation performance.

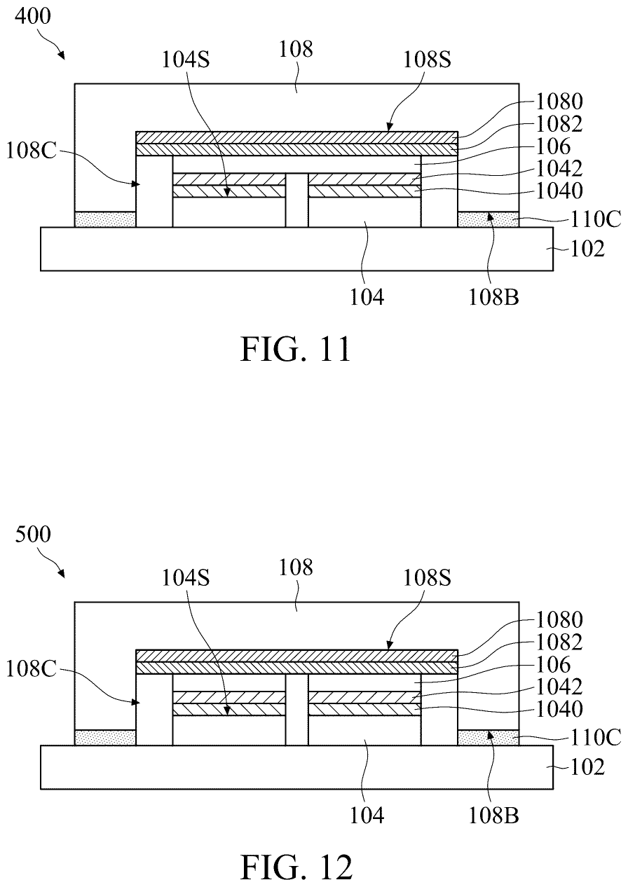

In some embodiments, the package structure 400 as shown in FIG. 11 is similar to the package structure 100 as shown in FIG. 5, except that there is more than one chip 104 disposed on the substrate 102, and the single thermal interface material 106 covers all the chips 104. By covering all the chips 104 with the single thermal interface material 106, the process is simplified. It should be noted that although only two chips 104 are illustrated in FIG. 11, the present disclosure is not limited thereto. In other embodiments, various numbers of the chips may be disposed on the substrate 102 according to practical requirements such as three, four, and more chips 104.

In some embodiments, the package structure 500 as shown in FIG. 12 is similar to the package structure 400 as shown in FIG. 11, except that the thermal interface material 106 includes a plurality of discrete segments spaced apart from each other, with each segment corresponding to a respective chip 104 in a one-to-one manner, rather than using the single thermal interface material 106 to cover all the chips 104 as shown in FIG. 11. By allowing each segment of the thermal interface material 106 to correspond to each chip 104 in a one-to-one manner, it becomes possible to tailor the thermal interface material 106 to the specific needs of each chip 104, such as variations in material properties or operating temperatures. In addition, since the single thermal interface material 106 is not used to cover all the chips, the amount of the thermal interface material 106 may be saved, and thus the production cost is reduced.

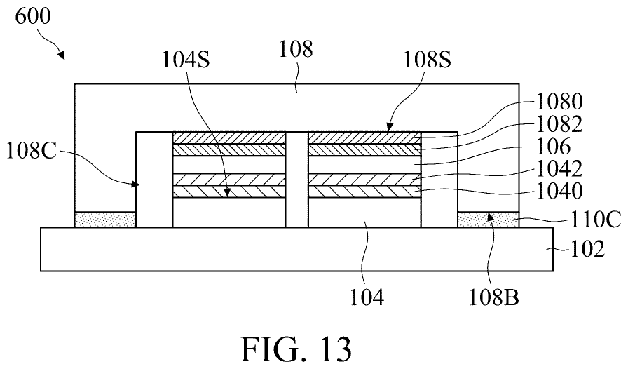

In some embodiments, the package structure 600 as shown in FIG. 13 is similar to the package structure 500 as shown in FIG. 12, except that both the metal layer 1080 and the outermost metal layer 1082 of the heat sink 108 include the discrete segments spaced apart from each other, with each segment corresponding to a respective chip 104 in a one-to-one manner, and the segments of the outermost metal layer 1082 corresponding to each chip 104 in a one-to-one manner. Thus it becomes possible to tailor the thermal interface material 106 to the specific needs of each chip 104, such as variations in material properties or operating temperatures. In addition, since the single thermal interface material 106 is not used to cover all the chips, the amount of the thermal interface material 106 may be saved, and thus the production cost is reduced. Although each segment of the metal layer 1080 and each segment of the outermost metal layer 1082 are illustrated as corresponded to each chip 104 in a one-to-one manner in FIG. 13, the present disclosure is not limited thereto. The heat sink 108 may include a single outermost metal layer 1082 (such as the outermost metal layer 1082 as shown in FIGS. 5, 9-12), the discrete segments of the metal layer 1080 spaced apart from each other (such as the metal layer 1080 as shown in FIG. 13), and the segments of the metal layer 1080 corresponding to each chip 104 in a one-to-one manner. In addition, in other embodiments, the heat sink 108 may include a single metal layer 1080 (such as the metal layer 1080 as shown in FIGS. 5, 9-12), discrete segments of the outermost metal layer 1082 spaced apart from each other (such as the outermost metal layer 1082 as shown in FIG. 13), and segments of the outer metal layer 1082 corresponding to each chip 104 in a one-to-one manner.

Although the heat sink 108 is illustrated as the heat-dissipating metal lid in FIGS. 11-13, the present disclosure is not limited thereto. The heat sink 108 may also be the cooling fin. In addition, another heat sink 108F may also be disposed on the heat sink 108 (as shown in FIG. 9), and the heat sink 108F may be a cooling fin to further increase the heat dissipation area to achieve a better heat dissipation performance.

In some embodiments, the outermost metal layer 1042, 1082 may be partially or completely fused into the thermal interface material 106, depending on the thickness of the outermost metal layer 1042, 1082. After the packaging is completed, at a bonding site between the thermal interface material 106 and the outermost metal layer 1042, 1082, the thermal interface material 106 reacts with the outermost metal layer 1042, 1082 due to the heat generated during the operation of the chip. Therefore, when the thickness of the outermost metal layer 1042, 1082 is relatively thin (such as Au with a thickness less than 0.1 μm), the outermost metal layer 1042, 1082 may completely fuse into the thermal interface material 106, and when a thickness of the outermost metal layer 1042, 1082 is relatively thick, since only a part of the outermost metal layer 1042, 1082 is fused into the thermal interface material 106, the other part of the outermost metal layer 1042, 1082 that is not fused into the thermal interface material 106 may still be observed.

Several examples and comparative examples are provided below to specifically describe the effects that can be achieved by bonding the metal layer and the thermal interface material in the embodiment of the present disclosure.

### Comparative Example 1: Directly Disposing the Thermal Interface Material onto the Chip

In Comparative Example 1, the chip 104 having the metal layer 1040 (made of a material of Al/Ti/NiV) and the outermost metal layer 1042 (made of a material of Au) was provided, and a 100 square millimeters (10 mm×10 mm) thermal interface material 106 (made of a material of 100 wt % indium) was directly disposed on the outermost metal layer 1042 without using any organic adhesive to obtain Comparative Example 1. Since the step of applying pressure to the thermal interface material was not performed, the force of applying pressure is presented as 0.0 gram-force/square millimeter (gf/mm²) in Table 1 below.

### Examples 1-7: Disposing the Thermal Interface Material onto the Chip Through the Indentation Bonding

In Examples 1-7, the chip 104 having the metal layer 1040 (made of a material of Al/Ti/NiV) and the outermost metal layer 1042 (made of a material of Au) was first provided, and the 100 square millimeters (10 mm×10 mm) thermal interface material 106 (made of a material of 100 wt % indium) was disposed on the outermost metal layer 1042 through indentation bonding as a bonding step without using any organic adhesive. Specifically, in an environment with a temperature of 18 to 20° C., pressure was applied at two points on the thermal interface material 106 by press heads 700 to cause the thermal interface material 106 to form a diffusion bond with the outermost metal layer 1042 of the chip 104 at the points of pressure to obtain Examples 1-7. During the two-point pressure application step of Examples 1-7, the force applied at each point were 1.0 gram-force/square millimeter (gf/mm²), 1.6 gram-force/square millimeter (gf/mm²), 2.5 gram-force/square millimeter (gf/mm²), 3.3 gram-force/square millimeter (gf/mm²), 4.3 gram-force/square millimeter (gf/mm²), 5.0 gram-force/square millimeter (gf/mm²), and 5.8 gram-force/square millimeter (gf/mm²).

### [Bonding Test]

After completing the manufacture of Comparative Example 1 and Examples 1-7, the chip 104 that had been bonded with the thermal interface material 106 in Comparative Example 1 and Examples 1-7 was attached to a turntable of a spin tool, after the turntable was spun at a set spin speed for 20 seconds, and the thermal interface material 106 on the chip 104 was observed to check whether it has fallen off. The results of the bonding test are shown in Table 1. In Table 1, “Bonded” indicates that the thermal interface material 106 was still bonded to the chip 104 after spinning, and “Fallen off” indicates that the thermal interface material 106 was fallen off from the chip 104 after spinning.

TABLE 1

| | Force | spin speed (rpm) | | | | | |
|---|---|---|---|---|---|---|---|
| | (gf/mm²) | 10 | 50 | 100 | 500 | 1,000 | 2,000 |
| Comparative | 0.0 | Fallen | Fallen | Fallen | Fallen | Fallen | Fallen |
| Example 1 | | off | off | off | off | off | off |
| Example 1 | 1.0 | Bonded | Fallen | Fallen | Fallen | Fallen | Fallen |
| | | | off | off | off | off | off |
| Example 2 | 1.6 | Bonded | Bonded | Fallen | Fallen | Fallen | Fallen |
| | | | | off | off | off | off |
| Example 3 | 2.5 | Bonded | Bonded | Bonded | Fallen | Fallen | Fallen |
| | | | | | off | off | off |
| Example 4 | 3.3 | Bonded | Bonded | Bonded | Bonded | Fallen | Fallen |
| | | | | | | off | off |
| Example 5 | 4.3 | Bonded | Bonded | Bonded | Bonded | Bonded | Bonded |
| Example 6 | 5.0 | Bonded | Bonded | Bonded | Bonded | Bonded | Bonded |
| Example 7 | 5.8 | Bonded | Bonded | Bonded | Bonded | Bonded | Bonded |

According to the results as shown in Table 1, since the thermal interface material 106 was not affixed to the chip 104 through indentation bonding in Comparative Example 1, the thermal interface material 106 had fallen off from the chip 104 at a spin speed of 10 rpm. In comparison, in Examples 1-4, as the force applied to each point during the two-point pressure application increased (from 1.0 gram-force/square millimeter (gf/mm²) to 3.3 gram-force/square millimeter (gf/mm²)), the bonding between the thermal interface material 106 and the chip 104 improves. In addition, in Examples 5-7, as the force applied to each point during the two-point pressure application increased to 4.3 gram-force/square millimeter (gf/mm²) or more, the thermal interface material 106 remained firmly bonded to the chip 104 even at a high spin speed of 2,000 rpm. These results confirm that fixation of the thermal interface material 106 through indentation bonding effectively achieves the desired positioning of the thermal interface material 106.

In summary, the present disclosure provides the package structure and the packaging method thereof which eliminates the need for the organic adhesive between the chip and the heat sink. By bonding the thermal interface material to the chip or the heat sink through indentation bonding before pressing the chip and the heat sink together, the thermal interface material is directly contacted and fixed onto the chip or heat sink, achieving temporary positioning. This prevents the thermal interface material from slipping out of place before the chip and heat sink are pressed together, thereby eliminating the need for the organic adhesive used in the existing techniques. Therefore, the cost of acquiring and disposing the organic adhesive may be saved, and achieve better heat dissipation. In addition, the risk of solid residue from the organic adhesive causing voids at the bonding surface may be avoided, and the reliability and the heat dissipation performance of the package structure are further enhanced.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a substrate;
a chip disposed on the substrate and having a backside surface away from the substrate;
a heat sink disposed above the substrate, wherein the heat sink has a surface facing the backside surface of the chip; and
a thermal interface material disposed between the chip and the heat sink, wherein there is no organic adhesive between the chip and the heat sink.

2. The package structure of claim 1, wherein the chip comprises a metal layer on the backside surface, wherein the metal layer comprises at least one of Al/Ti/NiV, Al/Cr/NiV, Al/NiV, Al/W, Ti/NiV, TiW, WTi, WTi/Ti, Cr/NiV, Cr, W, Ti/Ni, Al/Ti/Ni and Ti, and has a thickness of 0.001 to 10 μm.

3. The package structure of claim 2, wherein the chip further comprises an outermost metal layer adjacent to the thermal interface material, the outermost metal layer comprises at least one of Au, Ag, Cu, Rh, Ir, Pd and Pt, and has a thickness of 0.001 to 10 μm.

4. The package structure of claim 3, wherein the outermost metal layer of the chip is configured to at least partially fuse into the thermal interface material.

5. The package structure of claim 1, wherein the heat sink comprises a metal layer on the surface, and the metal layer comprises at least one of Au, Ag, Cu, Ti, Ti/Ni, Ni and W, and has a thickness of 0.001 to 10 μm.

6. The package structure of claim 5, wherein a number of the chip is plural, and the metal layer of the heat sink comprises a plurality of discrete segments spaced apart from each other corresponding to the chips.

7. The package structure of claim 5, wherein the heat sink further comprises an outermost metal layer adjacent to the thermal interface material, and the outermost metal layer comprises at least one of Au, Ag, Cu, Rh, Ir, Pd and Pt, and has a thickness of 0.001 to 10 μm.

8. The package structure of claim 7, wherein a number of the chip is plural, and the outermost metal layer of the heat sink comprises a plurality of discrete segments spaced apart from each other, corresponding to the chips.

9. The package structure of claim 7, wherein the outermost metal layer of the heat sink is configured to at least partially fuse into the thermal interface material.

10. The package structure of claim 1, wherein a number of the chip is plural, and the thermal interface material comprises a plurality of discrete segments spaced apart from each other, corresponding to the chips.

11. The package structure of claim 1, wherein the thermal interface material comprises indium-based alloy, wherein the indium-based alloy comprises at least one of:
30 to 35 wt % of Bi, 15 to 18 wt % of Sn and a balance of In, with a melting point of 55 to 65° C.;
30 to 35 wt % of Bi and a balance of In, with a melting point of 70 to 75° C.;
52 to 60 wt % of Bi, 15 to 18 wt % of Sn and a balance of In, with a melting point of 80 to 85° C.;
48 to 50 wt % of Sn and a balance of In, with a melting point of 110 to 120° C.; and
0.1 to 15 wt % of Ag and a balance of In, with a melting point of 140 to 280° C.

12. The package structure of claim 1, wherein the thermal interface material is pure indium and has a melting point of 150 to 160° C.

13. The package structure of claim 1, wherein coverage of the thermal interface material on the chip is greater than 90%.

14. The package structure of claim 1, wherein the heat sink is a heat-dissipating metal lid and/or a cooling fin.

15. The package structure of claim 1, wherein the material of the heat sink comprises at least one of Cu, Al, Co, Ni, nickel-plated copper, alloy, silicon carbide, aluminum nitride, graphite, or a combination thereof.

16. A packaging method, comprising:
disposing a chip on a substrate, wherein the chip has a backside surface away from the substrate;
providing a heat sink, wherein the heat sink has a surface facing the backside surface of the chip;
disposing a thermal interface material onto the chip or the heat sink through indentation bonding; and
bonding the heat sink to the chip so that the thermal interface material is disposed between the chip and the heat sink.

17. The packaging method of claim 16, wherein the indentation bonding comprises applying pressure at a single point to the thermal interface material to affix the thermal interface material to the chip or the heat sink.

18. The packaging method of claim 16, wherein the indentation bonding comprises applying pressure at multiple points to the thermal interface material to affix the thermal interface material to the chip or the heat sink.

19. The packaging method of claim 16, wherein the indentation bonding comprises applying a force greater than 0.1 gf/mm² to the thermal interface material at a temperature above 0° C. to affix the thermal interface material to the chip or the heat sink.

20. The packaging method of claim 16, wherein the step of bonding the heat sink to the chip comprises performing a hot press process to make coverage of the thermal interface material melted onto the chip greater than 90%.

21. The packaging method of claim 20, wherein the step of the hot press process comprises applying a force greater than 1 gf/cm² to the heat sink for 2 seconds to 10 minutes at a temperature above 50° C. in a process chamber under pressure or vacuum.

22. The packaging method of claim 16, further comprising forming a metal layer onto the backside surface of the chip before disposing the thermal interface material onto the chip.

23. The packaging method of claim 16, wherein before disposing the thermal interface material onto the chip, the method further comprises forming an outermost metal layer onto the metal layer of the backside surface of the chip.

24. The packaging method of claim 23, wherein the outermost metal layer of the chip is at least partially fused into the thermal interface material.

25. The packaging method of claim 16, wherein before disposing the thermal interface material onto the heat sink, the method further comprises forming a metal layer onto the surface of the heat sink.

26. The packaging method of claim 16, wherein before disposing the thermal interface material onto the heat sink, the method further comprises forming an outermost metal layer onto the metal layer of the surface of the heat sink.

27. The packaging method of claim 26, wherein the outermost metal layer of the heat sink is at least partially fused into the thermal interface material.

28. The packaging method of claim 16, wherein the heat sink is a heat-dissipating metal lid, and after bonding the heat sink to the chip, the package method further comprises disposing a cooling fin onto the heat-dissipating metal lid.
